(19) United States
(12) Patent Application Publication
(10) Pub. No.: US 2025/0299907 A1
(43) Pub. Date: Sep. 25, 2025

(54) LINER WITH RAISED RIBS FOR PARTICLE TRANSPORT REDUCTION

(71) Applicant: Axcelis Technologies, Inc., Beverly, MA (US)

(72) Inventors: David M. Burtner, Belmont, MA (US); Edward Eisner, Lexington, MA (US); Bo Vanderberg, Gloucester, MA (US); David Kirkwood, Arlington, MA (US)

(21) Appl. No.: 19/084,016

(22) Filed: Mar. 19, 2025

Related U.S. Application Data
(60) Provisional application No. 63/567,913, filed on Mar. 20, 2024.

(51) Int. Cl. H01J 37/16; H01J 37/317

(52) U.S. Cl. CPC H01J 37/16; H01J 37/3171; H01J 2237/0213

(57) ABSTRACT

A liner for an ion implanter includes a base and a plurality of ribs extending from a surface of the base. Each of the ribs includes a first surface that extends at an angle from the surface of the base toward a distal end and a second surface that extends from the distal end toward the surface of the base at a non-perpendicular angle.

### CROSS-REFERENCE TO RELATED APPLICATIONS

This application claims priority to U.S. Provisional Patent Application No. 63/567,913, filed on Mar. 20, 2024, the entire disclosure of which is incorporated herein by reference.

### FIELD OF THE DISCLOSURE

This disclosure relates to ion implantation and, more particularly, to particle reduction during ion implantation.

### BACKGROUND OF THE DISCLOSURE

In the manufacture of semiconductor devices, ion implantation is used to dope semiconductors with impurities. Ion implantation systems are often used to implant a workpiece, such as a semiconductor wafer, with ions from an ion beam to produce n-type or p-type material doping or to form passivation layers during fabrication of an integrated circuit. Such beam treatment can selectively implant the wafers with impurities of a specified dopant material, at a predetermined energy level, and in controlled concentration to produce a semiconductor material during fabrication of an integrated circuit. When used for doping semiconductor wafers, the ion implantation system injects a selected ion species into the workpiece to produce the desired extrinsic material. Implanting ions generated from source materials such as antimony, arsenic, or phosphorus, for example, results in an “n-type” extrinsic material workpiece, whereas a “p-type” extrinsic material workpiece often results from ions generated with source materials such as boron, gallium, or indium.

A typical ion implanter includes an ion source, an ion extraction device, a mass analysis device, a beam transport device, and a process chamber. The ion source generates ions of desired atomic or molecular dopant species. These ions are extracted from the source by an extraction system, typically a set of electrodes, which energize and direct the flow of ions from the source, forming an ion beam. Desired ions are separated from the ion beam in a mass analysis device, typically a magnetic dipole performing mass dispersion or separation of the extracted ion beam. The beam transport device, typically a vacuum system containing a series of focusing devices, transports the ion beam to the wafer processing device while maintaining desired properties of the ion beam. Finally, workpieces are transferred in and out of the process chamber via a workpiece handling system, which may include one or more robotic arms, for placing a workpiece to be treated in front of the ion beam and removing treated workpieces from the ion implanter.

As the ion beam strikes surfaces within the implanter, such as the workpiece or hardware components, it causes atoms to be sputtered from and larger particles to be liberated from the surfaces. These atoms and larger particles then deposit themselves on other surfaces and can form a poorly-adhering thin film or loose particles. To prevent damage to expensive and difficult to replace components, and to make cleaning of the implanter easier, removable liners are used to cover the bulk of the internal surfaces (in-vacuum surfaces) of an implanter. For example, workpieces, such as semiconductor wafers, are often coated with photoresist material. This photoresist sputters and outgasses when exposed to the ion beam. This liberated material eventually builds up on other surfaces, like the liners. The particles can be transported by the ion beam from surfaces in the ion implanter back to the workpiece, which can damage devices on the workpiece. Furthermore, an ion implanter operating at high beam current can suffer from intermittent large particle excursions of short durations, which negatively affect devices on a workpiece. These large particle excursions can result in particle levels that are orders of magnitude beyond the typical number of particles.

### BRIEF SUMMARY OF THE DISCLOSURE

A liner is disclosed in a first embodiment. The liner includes a base and a plurality of ribs extending from a surface of the base. Each of the ribs includes a first surface that extends at an angle from the surface of the base toward a distal end and a second surface that extends from the distal end toward the surface of the base at a non-perpendicular angle. The angle for between the first surface and the surface of the base is from 30° to 95°. The ribs have a height from 3 mm to 10 mm extending from the surface of the base.

The second surface may extend from the distal end to the surface of the base. In an instance, a plane of the surface, the first surface, and the second surface form a right triangle.

The first surface may face a direction of travel of an ion beam.

A space on the surface of the base between two of the ribs may be textured.

The angle of the first surface may be approximately perpendicular with the surface of the base.

The second surface may extend from the first surface at an angle from 10° to 45°.

A pitch between the ribs may be configured to prevent an ion beam from striking a surface of the base with 5° divergence of the ion beam.

The liner may be fabricated of graphite, SiC, SiC-coated graphite, aluminum, or silicon-coated aluminum.

The first surface and/or the second surface may be textured.

An intersection between the first surface and the second surface at the distal end may be rounded or flat.

The liner may be positioned in a mass analysis device, a scanner, or a corrector of the ion implanter.

A method is provided in a second embodiment. The method includes directing an ion beam through a beamline that includes a liner. The liner includes a base and a plurality of ribs extending from a surface of the base. Each of the ribs includes a first surface that extends at an angle from the surface of the base toward a distal end and a second surface that extends from the distal end toward the surface of the base at a non-perpendicular angle. The angle for between the first surface and the surface of the base is from 30° to 95°. The ribs have a height from 3 mm to 10 mm extending from the surface of the base.

There may be a distance of at least 10 mm between the ion beam the distal end.

The angle of the first surface may be approximately perpendicular with the surface of the base.

The first surface may face a direction of travel of the ion beam.

A pitch between the ribs may be configured to prevent the ion beam from striking a surface of the base with 5° divergence of the ion beam.

The liner may be fabricated of graphite, SiC, SiC-coated graphite, aluminum, or silicon-coated aluminum.

The beamline may include a mass analysis device, a scanner, or a corrector.

### DESCRIPTION OF THE DRAWINGS

For a fuller understanding of the nature and objects of the disclosure, reference should be made to the following detailed description taken in conjunction with the accompanying drawings, in which:

FIG. 1 is a side view showing an embodiment of a liner with ribs relative to an ion beam;

FIG. 2 is a side view showing another embodiment of a liner with ribs relative to an ion beam;

FIG. 3 is a side view showing another embodiment of a liner with ribs relative to an ion beam; and

FIG. 4 is a diagram showing an embodiment of a vacuum system in accordance with the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

Ranges of values are disclosed herein. The ranges set out a lower limit value and an upper limit value. Unless otherwise stated, the ranges include all values to the magnitude of the smallest value (either lower limit value or upper limit value) and ranges between the values of the stated range.

The steps of the method described in the various embodiments and examples disclosed herein are sufficient to carry out the methods of the present invention. Thus, in an embodiment, the method consists essentially of a combination of the steps of the methods disclosed herein. In another embodiment, the method consists of such steps.

The inventors have shown in experiments that loose particles on the floor of an ion implanter's beamline can be lifted up by an ion beam when the ion beam is in close proximity to the particle-laden surfaces. Large numbers of particles can then be transported to the workpiece by the ion beam from as far away as the ion source. The inventors also have shown in experiments that periodically-spaced raised features on the beamline's lower surfaces can inhibit the ion beam's ability to pick up loose particles that come to rest between the raised features. These raised features reduce the ability of the ion beam to pick up loose particles by enforcing a distance between the edge of the ion beam and the particle-laden surface. Embodiments of the liners disclosed herein include such periodically-spaced raised features.

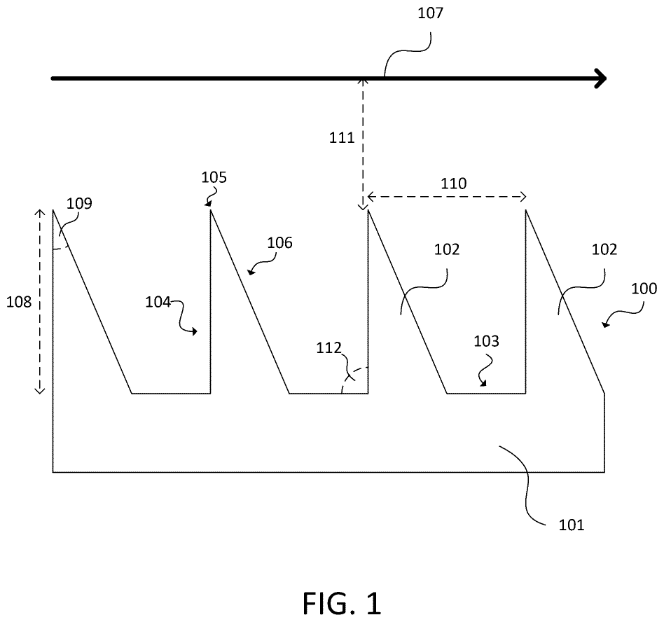

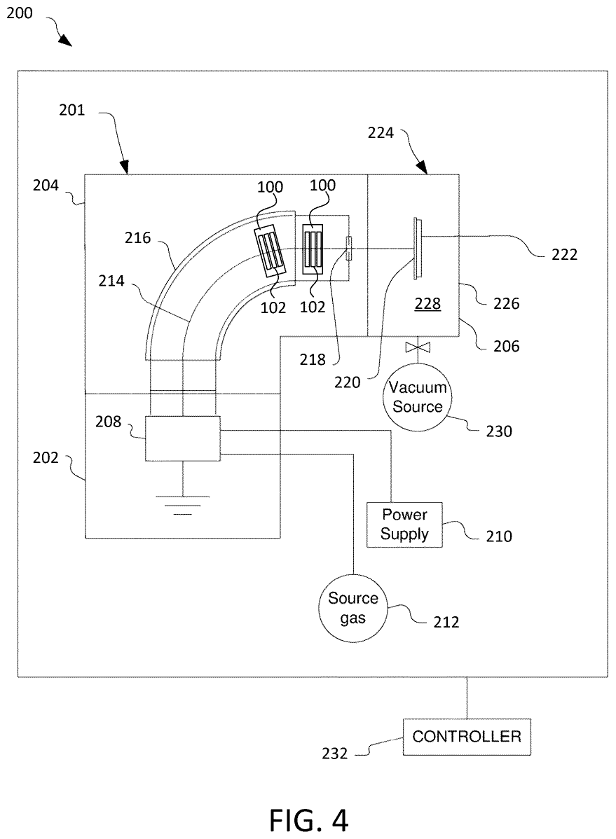

As shown in FIG. 1, a liner 100 for an ion implanter includes a base 101 and a plurality of ribs 102. The liner 100 is disposed on another component in the ion implanter, such as shown in the example of FIG. 4. The liner 100 can be fabricated out of graphite, silicon carbide, silicon carbide-coated graphite, aluminum, silicon-coated aluminum, or other materials. The base 101 and the ribs 102 can be fabricated of the same material or different materials. The base 101 can include apertures (not illustrated) for fasteners between the ribs 102. The base 101 also can include a fastening assembly (not illustrated) on the surface opposite the ribs 102. These fasteners or fastening assembly can enable a connection with other components in an ion implanter.

The ribs 102 extend from a surface 103 of the base 101 in the example of FIG. 1. The liner 100 can have more or fewer ribs 102 than that illustrated in FIG. 1. Each of the ribs 102 includes at least two surfaces. A first surface 104 extends approximately perpendicular from the surface 103 of the base 101 to a distal end 105 of the rib 102 in FIG. 1. For example, the first surface 104 may extend from the surface 103 of the base 101 at an angle 112 from 85° from 95° or from 89° to 91°. If the angle 112 is more than approximately 95° (i.e., the rib 102 bends to the right in FIG. 1) then the rib 102 may not be as effective because particles can come to rest on first surface 104, be lifted into the ion beam 107, and be transported elsewhere in the ion implanter. An angle 112 of approximately 90° will be more effective than an angle 112 of 95° and also may be easier to manufacture than other shapes. However, other shapes are possible.

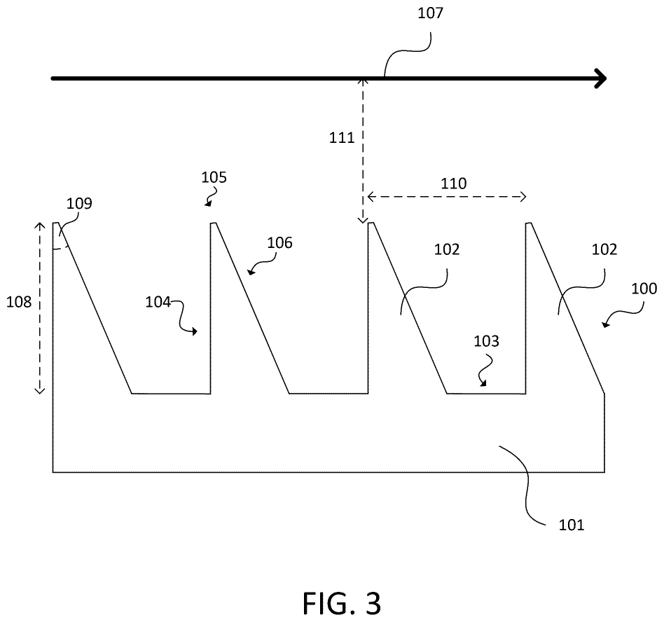

A second surface 106 extends from the distal end 105 toward the surface 103 of the base 101. The second surface 106 can extend in an unbroken line from the distal end 105 to the surface 103. In this instance, the rib 102 has a generally triangular cross-section. In another embodiment, the rib 102 has a generally polygonal cross-section when the distal end 105 is not just a point, such as that shown in FIG. 3. Another surface (not illustrated) also can be included as part of the rib 102. Thus, the rib 102 can be a prism or a pyramid. Each rib 102 can have the same shape or a different shape. Each rib 102 also can use the same angles or different angles.

An angle 112 of less than 90° (i.e., the rib 102 bends to the left in FIG. 1) is possible and may be beneficial because the ion beam 107 cannot easily lift particles from under the distal end 105 to above the rib 102. In this instance, the rib 102 can trap particles because the rib 102 is angled toward the direction of travel for particles in the ion beam. Thus, an angle 112 that is acute can be used. The angle 112 can be from 30° to 89°. For example, the angle 112 may be approximately 45°.

As shown in FIG. 1, the first surface 104 faces a direction of travel for particles in the ion beam 107. The ion beam 107 is directed through a beamline of an ion implanter that includes the ribs 102. Particles collect between the ribs 102 on the surface 103. The particles can be carbon, silicon from a wafer, or an implant species (e.g., Ge, As, B). Any particles are then shielded from the ion beam 107 between the ribs 102, which prevents the ion beam 107 from disturbing the particles. If the rib 102 bends to the left in FIG. 1 (i.e., the angle 112 is acute), then particles can be in a shadow of the rib 102.

In an embodiment, the surface 103 of the base 101, the first surface 104, and the second surface 106 can form a right triangle. The distal end 105 is a point, which minimizes the area presented to the ion beam 107. This can reduce buildup at a region closest to the ion beam 107. Other triangular shapes are possible and this is merely one example.

The first surface 104 can have a height 108 from 3 mm to 10 mm. In a particular example, the height 108 may be 3 mm to 5 mm or, more particularly, approximately 5 mm. A height 108 less than 3 mm may not be sufficient to shield the surface 103 from strikes by the ion beam 107. The inventors have found that, in general, the taller the rib 102 the more effective the rib 102 is at protecting the surface 103. However, the taller the rib 102 is, the more the rib 102 encroaches on the ion beam guide volume available to transport the ion beam 107, which will limit beam current for the ion beam 107. The ion beam 107 itself has a finite height that is a fraction of the ion beam guide volume. While the ion beam 107 is illustrated as a line in FIG. 1, the ion beam 107 can have gaussian distribution. If the ribs 102 are tall enough to clip the edges of the ion beam 107, then the ion beam 107 can create additional sputtered material and be counterproductive for particles.

The height 108 may vary depending on placement within an ion implanter. The ion beam 107 can have different beam parameters at different locations in the ion implanter. Thus, the height 108 may be adjusted to reflect this difference in, for example, beam size or chamber size. However, the height 108 is generally small enough that the rib 102 is not positioned in a direct path of the ion beam 107.

The second surface 106 can extend from the first surface 104 at an angle 109 from 10° to 45°. In a particular example, the angle 109 is approximately 30°. The second surface 106 is not facing the direction of the ion beam 107, so the second surface 106 does not need to trap particles. However, the second surface 106 can funnel particles toward the surface 103 of the base 101 depending on the angle of the second surface 106.

The width of the ribs 102 (extending into and out of the page in FIG. 1) can vary depending on the width of the ion beam 107, the scan pattern of the ion beam 107, or the width of the beamline component where the ribs 102 are located. The ribs 102 can have a width that extends across an entirety or less than an entirety of a beamline component of an ion implanter. More than one rib 102 can be placed in series across the width of a beamline component of an ion implanter.

The rib 102 should be spaced from an outer boundary of the ion beam 107 to prevent clipping the ion beam 107. Clipping the ion beam 107 can reduce beam current of the ion beam 107 and create additional particles. Some margin also may be added for drift of the ion beam 107. A distance 111 between the distal end 105 and an outer boundary of the ion beam 107 can be at least 10 mm, but the distance 111 can vary with the size of the ion beam 107.

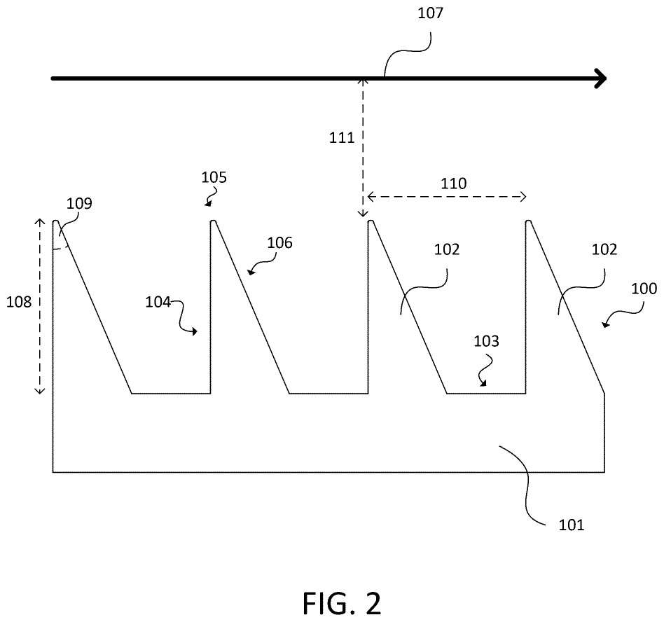

While illustrated as a point, the intersection between the first surface 104 and second surface 106 can be rounded (FIG. 2) or flat (FIG. 3). A rounded or flat intersection at the distal end 105 may be easier to machine and may lead to less breakage. Tapering an intersection between the first surface 104 and the second surface 106 to a fine point can lead to breakage during manufacturing, transport, installation, preventative maintenance, or cleaning, which results in exposed graphite. Thermal cycling of the ion beam on the intersection also can cause the sharp edges to crack due to inherent mechanical stress. However, a flat intersection (FIG. 3) can be configured to have a reduced or minimal length to prevent particles from collecting on the flat intersection near the ion beam 107. This reduces the particles or deposits that can left off during operation of the ion implanter.

A pitch 110 between the ribs 102 can be configured to prevent the ion beam 107 from striking or otherwise impinging a surface 103 of the base 101 before striking the next rib 102. This can prevent the ion beam 107 from disturbing the film or loose particles on the base 101. Such a film can have a thickness from 10 nm to a few microns. An ion beam 107 that strikes or otherwise impinges the surface 103 can remove loose particles or part of a film from the base 101 and cause it to travel elsewhere in the ion implanter (e.g., toward the workpiece that is implanted). This can negatively affect devices on the workpiece. The ion beam 107 may have, for example, a 5° divergence. This ion beam divergence can cause particles in the ion beam 107 to impact the first surface 104 of the ribs 102, but not the surface 103 of the base 101. In an example, the pitch 110 can be from 24 mm to 47 mm (e.g., 44 mm). The pitch 110 can depend on the height 108 of the rib 102. A larger height 108 can mean a larger pitch 110. In a particular example, the pitch 110 of the ribs 102 can be 25 mm for a height 108 of 3 mm.

In an instance, the space of the surface 103 between the two ribs 102, the first surface 104, and/or the second surface 106 are smooth. In another instance, the space of the surface 103 between the two ribs 102 can be textured or otherwise imbued with a surface roughness in excess of that found in, for example, graphite. This textured surface can improve adhesion or retention of particles on the surface 103. The texture also can be applied to a flat plane of the ribs 102. Partially-converted SiC also can be used on the ribs 102. Partially-converted SiC has a rough surface that will aid in film adhesion.

In an instance, the first surface 104 and/or the second surface 106 are textured. The first surface 104 and/or the second surface 106 can be textured with or without a texture on the surface 103. The first surface 104 and/or the second surface 106 can be textured or otherwise imbued with a surface roughness in excess of that found in, for example, graphite. This textured surface can improve adhesion or retention of particles on the first surface 104 or the second surface 106.

The inventors found that ribs 102 with a larger height 108 were more effective at inhibiting short duration large particle excursions. The ion beam 107 was farther from the surface 103 due to the presence of the ribs 102, which resulted in fewer particles on the surface 103.

FIG. 4 illustrates an exemplified vacuum system 200 that may implement various apparatus, systems, and methods of the present disclosure. The vacuum system 200 includes an ion implantation system 201, however various other types of vacuum systems are also contemplated, such as plasma processing systems or other semiconductor processing systems. The ion implantation system 201, for example, comprises a terminal 202, a beamline assembly 204, and an end station 206.

Generally speaking, an ion source 208 in the terminal 202 is coupled to a power supply 210, whereby a gas from a gas source 212 (also called a dopant gas) supplied thereto and/or material from a target is ionized into a plurality of ions to form an ion beam 214 (such as ion beam 107). The ion beam 214 is directed through a beam-steering apparatus 216 and out an aperture 218 toward the end station 206. In the end station 206, the ion beam 214 bombards a workpiece 220 (e.g., a semiconductor such as a silicon wafer, a display panel, etc.), which is selectively clamped or mounted to a chuck 222 (e.g., an electrostatic chuck). Once embedded into the lattice of the workpiece 220, the implanted ions change the physical and/or chemical properties of the workpiece 220. Because of this, ion implantation is used in semiconductor device fabrication and in metal finishing, as well as various applications in materials science research.

The ion beam 214 of the present disclosure can take any form, such as a pencil or spot beam, a ribbon beam, a scanned beam, or any other form in which ions are directed toward end station 106, and all such forms are contemplated as falling within the scope of the disclosure.

The end station 206 includes a process chamber 224, such as a vacuum chamber 226, wherein a process environment 228 is associated with the process chamber. The process environment 228 within the process chamber 224, for example, comprises a vacuum produced by a vacuum source 230 (e.g., a vacuum pump) coupled to the process chamber 224 and configured to substantially evacuate the process chamber 224. A controller 232 is provided for overall control of the vacuum system 200.

The ion source 208 (also called an ion source chamber), for example, can be constructed using refractory metals (W, Mo, Ta, etc.) and graphite in order to provide suitable high temperature performance, whereby such materials are generally accepted by semiconductor manufacturers. The gas from the gas source 212 is used within the ion source 208. The gas may or may not be conductive in nature.

An embodiment of the liner 100 can be included as part of the ion implantation system 201, as shown in FIG. 4. The ribs 102 can be placed at various locations within the ion implantation system 201. For example, the ribs 102 can be included in liners 100 in the mass analysis device or other beam-steering apparatus, scanner, or corrector. Thus, the ribs 102 can be placed in the beam-steering apparatus 216, though the ribs 102 can be placed in other locations in the ion implantation system 201. Two liners 100 with three ribs 102 are illustrated on the floor of the beam steering apparatus 216 near the aperture 218. While shown with three ribs 102 for simplicity, other numbers of ribs 102 can be used.

The ribs 102 can be placed on surfaces below the ion beam 214, above the ion beam 214, and/or on one or more sides of the ion beam 214. van der Walls forces may be sufficient for particles to overcome gravity and adhere to surfaces above the ion beam 214. Thus, the ribs 102 can be placed on all surface within a beamline component of the ion implantation system 201 and not just on the base of such a beamline component.

For example, FIG. 4 shows a beam steering apparatus 216 with a liner 100 that has a series of ribs 102 along a path of the ion beam. In an embodiment, some of the ribs 102 are approximately 200 mm wide arranged symmetric about the curve in the beam steering apparatus 216 whereas other ribs 102 are parallel to each other. In another embodiment, alternating ribs 102 have different lengths. Every other rib 102 may be longer to fit with the curvature of the beam steering apparatus 216. The ribs 102 can have a height from 3 mm to 5 mm or from 5 mm to 10 mm. The sides of the ribs 102 may avoid touching the top or bottom of the ion implanter in the space 302.

The embodiments of the present disclosure also may be implemented in various semiconductor processing equipment such as chemical vapor deposition (CVD), physical vapor deposition (PVD), metal organic chemical vapor deposition (MOCVD), etching equipment, and various other semiconductor processing equipment, and all such implementations are contemplated as falling within the scope of the present disclosure.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A liner for an ion implanter comprising:
a base; and
a plurality of ribs extending from a surface of the base, wherein each of the ribs includes a first surface that extends at an angle from the surface of the base toward a distal end and a second surface that extends from the distal end toward the surface of the base at a non-perpendicular angle, wherein the angle for between the first surface and the surface of the base is from 30° to 95°, and wherein the ribs have a height from 3 mm to 10 mm extending from the surface of the base.

2. The liner of claim 1, wherein the second surface extends from the distal end to the surface of the base.

3. The liner of claim 2, wherein a plane of the surface, the first surface, and the second surface form a right triangle.

4. The liner of claim 1, wherein the first surface faces a direction of travel of an ion beam.

5. The liner of claim 1, wherein a space on the surface of the base between two of the ribs is textured.

6. The liner of claim 1, wherein the angle of the first surface is approximately perpendicular with the surface of the base.

7. The liner of claim 1, wherein the second surface extends from the first surface at an angle from 10° to 45°.

8. The liner of claim 1, wherein a pitch between the ribs is configured to prevent an ion beam from striking a surface of the base with 5° divergence of the ion beam.

9. The liner of claim 1, wherein the liner is fabricated of graphite, SiC, SiC-coated graphite, aluminum, or silicon-coated aluminum.

10. The liner of claim 1, wherein the first surface and/or the second surface are textured.

11. The liner of claim 1, wherein an intersection between the first surface and the second surface at the distal end is rounded or flat.

12. The liner of claim 1, wherein the liner is positioned in a mass analysis device, a scanner, or a corrector of the ion implanter.

13. A method comprising:
directing an ion beam through a beamline that includes a liner, wherein the liner includes:
a base; and
a plurality of ribs extending from a surface of the base, wherein each of the ribs includes a first surface that extends at an angle from the surface of the base toward a distal end and a second surface that extends from the distal end toward the surface of the base at a non-perpendicular angle, wherein the angle for between the first surface and the surface of the base is from 30° to 95°, and wherein the ribs have a height from 3 mm to 10 mm extending from the surface of the base.

14. The method of claim 13, wherein there is a distance of at least 10 mm between the ion beam the distal end.

15. The method of claim 13, wherein the angle of the first surface is approximately perpendicular with the surface of the base.

16. The method of claim 13, wherein the first surface faces a direction of travel of the ion beam.

17. The method of claim 13, wherein a pitch between the ribs is configured to prevent the ion beam from striking a surface of the base with 5° divergence of the ion beam.

18. The method of claim 13, wherein the liner is fabricated of graphite, SiC, SiC-coated graphite, aluminum, or silicon-coated aluminum.

19. The method of claim 13, wherein the beamline includes a mass analysis device, a scanner, or a corrector.
